(19) United States
(12) Patent Application Publication
(10) Pub. No.: US 2025/0344479 A1
(43) Pub. Date: Nov. 6, 2025

(54) THIN-FILM TRANSISTOR AND MANUFACTURING METHOD THEREOF

(71) Applicant: SEOUL NATIONAL UNIVERSITY R&DB FOUNDATION, Seoul (KR)

(72) Inventors: Soo Yeon LEE, Seoul (KR); Soo Bin An, Seoul (KR)

(73) Assignee: SEOUL NATIONAL UNIVERSITY R&DB FOUNDATION, Seoul (KR)

(21) Appl. No.: 18/884,286

(22) Filed: Sep. 13, 2024

(30) Foreign Application Priority Data
May 3, 2024 (KR) 10-2024-0058988

(51) Int. Cl. H01L 29/40; H01L 29/66; H01L 29/786

(52) U.S. Cl. CPC H10D 64/118; H10D 30/6755; H10D 99/00

(57) ABSTRACT

The thin film transistor according to one example of the present invention may comprise; a substrate; a gate electrode formed on the substrate; an insulating layer formed on the substrate to cover the gate electrode; a semiconductor layer formed on the insulating layer to form a channel; a source electrode and a drain electrode formed spaced apart from each other on the semiconductor layer; and a capping layer formed in at least one region between the source electrode and the drain electrode on the semiconductor layer to control the carrier concentration of the channel.

### CROSS REFERENCE TO RELATED APPLICATION

This application claims priority to Korean Patent Application No. 10-2024-0058988 filed May 3, 2024, the entire disclosure of which is incorporated herein by reference.

### TECHNICAL FIELD

The present invention relates to a thin film transistor and a manufacturing method thereof.

### BACKGROUND ART

A Thin Film Transistor is a transistor with a multi-layer structure in which thin films are stacked. The thin film transistor, a type of semiconductor device, are used, for example, for displays, and controls electrical signals and plays a switch role of individually on-off (switching) each pixel. It has advantages of improving screen image quality and providing high resolution and fast response speed, due to these operating characteristics.

The thin film transistor generally has components such as a channel layer, a gate related to the channel layer, a source and a drain, an insulating layer between the gate and channel layer, a capping layer and the like, and when forming each of them, a process such as vacuum deposition, sputtering, chemical vapor deposition, atomic layer deposition and the like is used.

When a capping layer is formed on a conventional thin film transistor, largely, 2 kinds of methods are used. The first is a method of repeatedly laminating channel layers and capping layers alternately using ALD (atomic layer deposition), and the second is a method of applying aluminum oxide on a thin film transistor using EHD jet printing (electrohydrodynamic jet printing). By the two kinds of methods, the mobility of the thin film transistor and the performance in a low gray level region can be improved.

However, in the first method, there is a problem that the complexity of the process increases exponentially, and in the second method, a problem that the complexity of the process increases and the transfer curve of the transistor is distorted may occur.

Accordingly, research on methods to improve the mobility of the thin film transistor and the display performance in a low gray level region while reducing the complexity of the process is continuing.

### DISCLOSURE

### Technical Problem

An object of the present invention lowers the complexity of the process of thin film transistors and enhances the SS (subthreshold swing) and mobility.

However, problems to be solved by the present invention are not limited to the contents described above.

### Technical Solution

The thin film transistor according to one aspect of the present invention may comprise a substrate; a gate electrode formed on the substrate; an insulating layer formed on the substrate to cover the gate electrode; a semiconductor formed on the insulating layer to form a channel; a source electrode and a drain electrode formed spaced apart from each other on the semiconductor layer; and a capping layer formed in at least one region between the source electrode and the drain electrode on the semiconductor layer to control the carrier concentration of the channel.

According to one example, the capping layer may comprise at least one selected from the group consisting of aluminum oxide (Al₂O₃), silicon oxide (SiO₂), silicon nitride (SiN_{X}) and inorganic insulating materials, and the carrier concentration of the region in which the capping layer is formed may be higher than the carrier concentration of a region in which the capping layer is not formed.

According to one example, the thickness of the capping layer may be 2 nm to 10 nm.

According to one example, the width and length of the capping layer may be equal to or smaller than the width and length of the channel, respectively.

According to one example, the width of the capping layer may be 50% or less of the width of the channel.

According to one example, the width direction formation position of the capping layer may satisfy the value of [Equation 1] below in relation to the channel.

$$X = k ( {W}_{CH} - {W}_{CAP} ) , ( 0 \leq k \leq 1 ) \qquad [ Equation 1 ]$$

(Herein, X is the width direction distance from one end of the semiconductor layer to the location where the capping layer starts, and W_{CH} is the width of the channel, and WCAP is the width of the capping layer)

According to one example, the length of the capping layer may be 95% or less of the length of the channel.

According to one example, the length direction formation position of the capping layer may satisfy the value of [Equation 2] below in relation to the channel.

$$Y = k ( {L}_{CH} - {L}_{CAP} ) , ( 0 \leq k \leq 1 ) \qquad [ Equation 2 ]$$

(Herein, Y is the vertical direction distance in the length direction, and LCH is the length of the channel, and LCAP is the length of the capping layer)

According to one example, the semiconductor layer positioned on the bottom of the region in which the capping layer is formed may perform the role of an N-type doping region.

According to one example, at least a part of the capping layer may be in contact with the source electrode and the drain electrode.

The manufacturing method of a thin film transistor proposed in another aspect of the present invention may comprise preparing a substrate; forming a gate electrode on the substrate; forming an insulating layer on the substrate to cover the gate electrode; forming a semiconductor layer on the insulating layer; forming a source electrode and a drain electrode spaced apart on the semiconductor layer; and forming a capping layer in at least a part of a region between the source electrode and drain electrode on the semiconductor layer.

According to one example, the forming an insulating layer, may comprise depositing an insulating material with a thickness of 100 nm to 200 nm on the substrate.

According to one example, the forming a capping layer may comprise forming the capping layer through a sputtering method at a room temperature.

According to one example, it may comprise determining a region in which the capping layer is to be positioned in consideration of the SS, threshold voltage and mobility values of the thin film transistor, before the forming the capping layer.

According to one example, the determining a region in which the capping layer is to be positioned may determine at least one of the location, width and length of the capping layer.

According to one example, the thin film transistor may be the thin film transistor of claim 1.

The circuit for displays comprising a thin film transistor suggested in other aspect of the present invention may be a circuit for displays comprising at least one thin film transistor for a switching or driving purpose, and the thin film transistor may be the thin film transistor of claim 1.

### Advantageous Effects

According to one example of the present invention, a method with low process complexity can be provided when a thin film transistor is manufactured.

According to one example of the present invention, a thin film transistor in which the transfer curve of the thin film transistor is not distorted can be provided.

According to one example of the present invention, a thin film transistor with improved SS and mobility can be provided.

According to one example of the present invention, a thin film transistor with improved performance in a low gray level region can be provided.

According to one example of the present invention, a thin film transistor having an effect of generating a parasitic transistor with electrical characteristics different from those of a unlaminated region, by partially laminating capping layers can be provided.

However, the effects of the present invention are not limited to the effects described above, and include all effects naturally embodied due to various configurations proposed in the present invention.

### BRIEF DESCRIPTION OF THE DRAWINGS

FIG. 1 schematically illustrates the thin film transistor according to one example of the present invention.

FIG. 2 schematically illustrates the thin film transistor according to another example of the present invention.

FIG. 3 is a graph of comparing and illustrating the changes in the threshold voltage by thickness of the capping layer according to one example of the present invention.

FIG. 4 is a graph of comparing and illustrating the transfer curves by width and length of the capping layer formed in the width direction of the channel layer according to one example of the present invention.

FIG. 5 is a table showing the SS by width and length of the capping layer formed in the width direction of the channel layer according to one example of the present invention.

FIG. 6 illustrates various types of capping layers formed in the width direction on the channel according to numerous examples of the present invention.

FIG. 7 is a graph of comparing and illustrating the transfer curves by length of the capping layer formed in the length direction of the channel layer according to one example of the present invention.

FIG. 8 is a table showing the SS by length of the capping layer formed in the length direction of the capping layer according to one example of the present invention.

FIG. 9 illustrates various types of capping layers formed in the length direction on the channel according to numerous examples of the present invention.

FIG. 10 is a graph showing the transfer curves of the capping layer formed in the length and width direction of the channel layer according to one example of the present invention.

FIG. 11 is a table showing the SS by length and width of the capping layer formed simultaneously in the width and length direction of the capping layer according to one example of the present invention.

FIG. 12 illustrates various types of capping layers formed in the length and width direction on the channel according to various examples of the present invention.

### MODE FOR INVENTION

Examples of the present disclosure are illustrated for the purpose of describing the technical spirit of the present disclosure. The scope according to the present disclosure are not limited to examples presented below or specific description of these examples.

All technical terms and scientific terms used in the present disclosure have meanings commonly understood by those skilled in the art to which the present disclosure belongs, unless otherwise defined. All terms used in the present disclosure are selected for the purpose of more clearly describing the present disclosure, and are not selected to limit the scope according to the present invention.

Expressions such as “comprising”, “providing”, “having” and the like used in the present disclosure, should be understood in open-ended terms encompassing the possibility of including other examples, unless otherwise stated in a phrase or sentence in which the corresponding expression is included.

Expressions in a singular form described in the present disclosure may include a meaning of a plural form unless otherwise stated, and this is equally applied to expressions in a singular form described in claims.

Hereinafter, with reference to the accompanied drawings, the examples of the present invention will be described. In addition, in the description of the following examples, overlapping description of identical or corresponding components may be omitted. However, even if description of components is omitted, it is not intended that such components are not included in any example.

A Thin Film Transistor is a semiconductor device, and for example, one of key components of a display screen used for individually controlling pixels of the display. The thin film transistor plays a role of controlling electrical signals using a semiconductor material in a thin film form.

According to the development of technology, thin film transistors are required to have higher mobility, lower power consumption, improvement of performance in a low gray level region, and the like, and accordingly, research and development of new processes and devices are in progress.

There is a way to use aluminum oxide as a method of improving functions of a thin film transistor. Mainly, a method of repeatedly laminating semiconductor layers and aluminum oxide alternately using ALD (atomic layer deposition) and a method of applying aluminum oxide on a general oxide semiconductor-based thin film transistor using EHD jet printing (electrohydrodynamic jet printing) are used.

However, the above methods have problems. In the first method, the complexity of the process increases exponentially due to the process of repeating laminating, and in the second method, a problem that the transfer curve of a thin film transistor is distorted occurs.

In the present invention, a technology capable of achieving high mobility and obtaining improvement of performance in a low gray level region by laminating aluminum-containing oxide, for example, aluminum oxide, on the channel layer of a new or conventionally completed thin film transistor, and controlling the thickness, form, and the like of the laminated aluminum oxide, is proposed, and a manufacturing process simpler than conventional technologies is proposed.

Hereinafter, referring to the attached drawings, the examples of the present invention will be described. In this process, the thickness or size or the like of the lines illustrated in the drawings may be exaggerated for clarity and convenience. In addition, in the description of the following examples, overlapping description of identical or corresponding components may be omitted. However, even if description of components is omitted, it is not intended that such components are not included in any example.

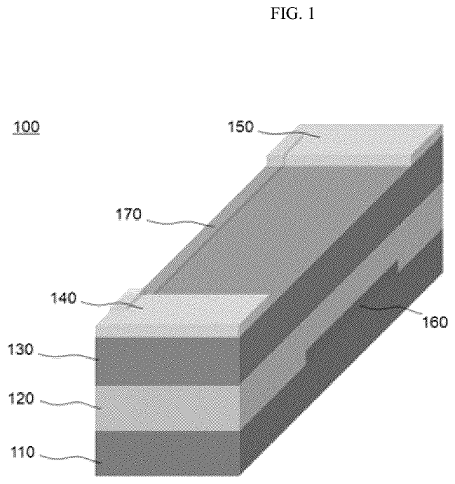

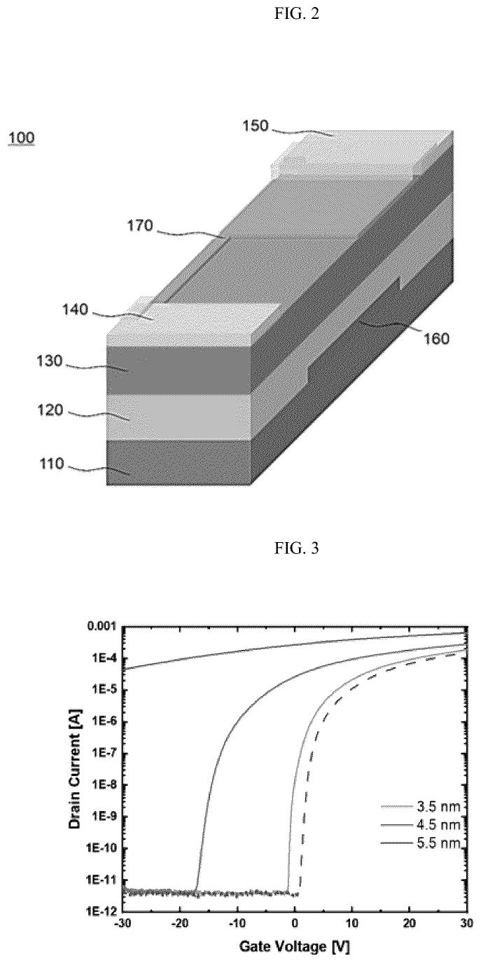

First, referring to FIG. 1 and FIG. 2, the thin film transistor according to one example of the present invention will be described.

In the present invention, a thin film transistor comprising a capping layer is proposed.

FIG. 1 schematically illustrates the thin film transistor according to one example of the present invention. FIG. 2 schematically illustrates the thin film transistor according to another example of the present invention. FIG. 1 and FIG. 2 represent the configuration of each layer constituting the thin film transistor, but in some examples of the present invention, the thin film transistor may be composed by omitting some of these configurations.

As shown in FIG. 1 and FIG. 2, in the thin film transistor according to one example of the present invention, a semiconductor layer forming a channel is formed after forming a gate electrode on a substrate, and an insulating layer is interposed between them. On the semiconductor layer, a source electrode and a drain electrode are formed spaced apart. In addition, on the semiconductor layer, in at least a part of region between the source electrode and the drain electrode, a capping layer which controls the carrier concentration of the channel may be formed.

Referring to FIG. 1 and FIG. 2, the substrate may be a high concentration of P type of doped substrate. Then, the substrate may be a substrate made of glass or other materials. On the substrate, a gate electrode/insulating layer may be formed. The gate electrode may be formed with any one metal material selected from the group consisting of Ti, Mo, Au and Ag. In addition, the insulating layer may comprise SiO₂, and may be formed with a thickness of 100 nm to 200 nm.

A semiconductor layer may be formed on the insulating layer and/or gate electrode. The semiconductor layer may be formed with a semiconductor material comprising one amorphous oxide selected from the group consisting of a-IGZO, a-ZnO, a-InO, and a-ITZO. On the semiconductor layer, a source electrode and a drain electrode may be formed spaced apart.

On the semiconductor layer, on the channel region between the source electrode and drain electrode, a capping layer that controls or adjusts the carrier concentration of the channel may be partially formed. The capping layer may be formed so that the concentration-adjusted region of the channel layer is physically or electrically connected to the source electrode and/or drain electrode, as at least a part of them is in contact with the source electrode and/or the drain electrode. At this time, the semiconductor layer positioned on the bottom of the region in which the capping layer is formed may have an increased carrier concentration related to the charge mobility due to the reaction between the capping layer and semiconductor layer.

The capping layer may be formed to cover a partial region of the semiconductor layer so as to form one shape of I type (as FIG. 1), T type (as FIG. 2) or H type lying at 90 degrees (not shown), when viewed from the top.

In the following, with FIG. 3, the changes in the threshold voltage by thickness of the capping layer will be described.

The capping layer may comprise at least one selected from the group consisting of aluminum oxide (Al₂O₃), silicon oxide (SiO₂), silicon nitride (SiN_{X}) and inorganic insulating materials. The carrier concentration of the region in which this capping layer is formed may be higher than the carrier concentration of the region in which the capping layer is not formed. As the thickness of the capping layer becomes thicker, the threshold voltage may become lover. When the capping layer is formed on the semiconductor layer, the carrier concentration of the channel may increase due to the reaction between the semiconductor layer and capping layer.

The thin film transistor in which the capping layer increasing the carrier concentration is formed in this way may have lower threshold voltage than a thin film transistor without a capping layer, and the value of the threshold voltage may be controlled at an appropriate level according to the needs of the user.

As shown in FIG. 3, it can be confirmed that the threshold voltage of the thin film transistor in which the capping layer is formed is lowered than the threshold voltage of the thin film transistor (black dotted line) in which the capping layer is not formed as a negative value.

In addition, the thickness of the capping layer may be 2 nm to 10 nm. As described above, as the thickness of the capping layer becomes thicker, the threshold voltage may move to the lower negative direction. The thin film transistor may be formed by appropriately adjusting the thickness of the capping layer within the above thickness range depending on the size of the required threshold voltage.

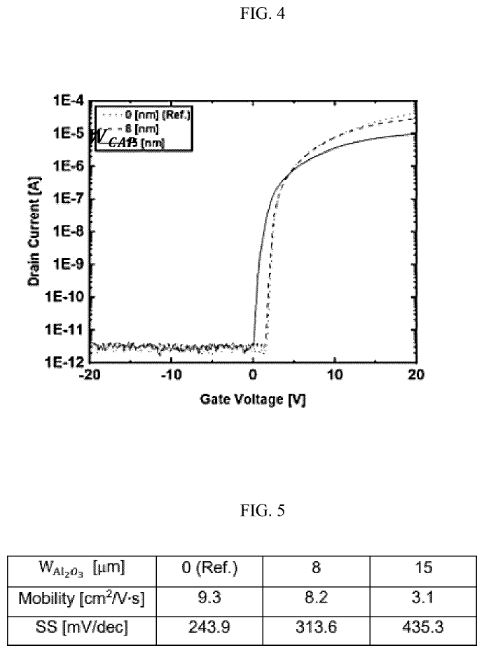

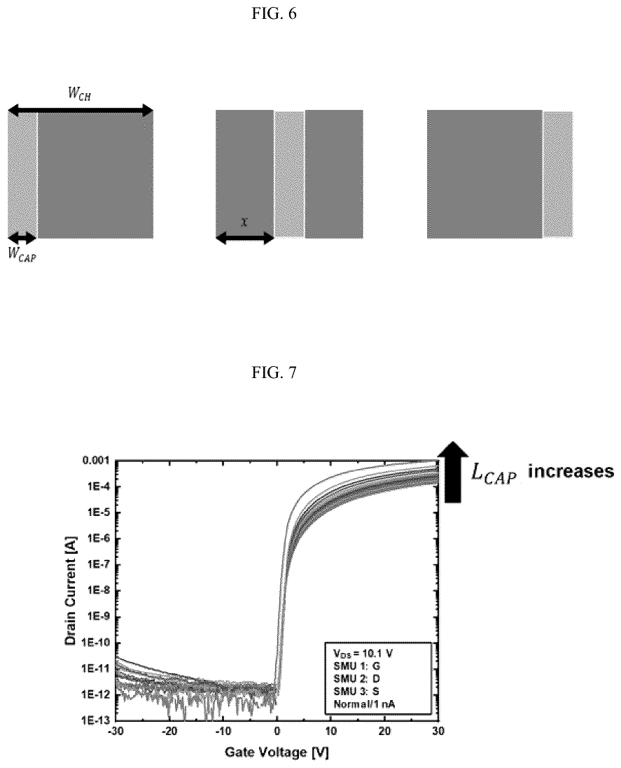

Hereinafter, with FIG. 4, FIG. 5 and FIG. 6, the transfer curve and changes in mobility and SS when the capping layer is formed in the width direction will be described.

FIG. 4 is a graph of the transfer curve by length when the capping layer is formed along the width direction, and FIG. 5 is a table showing the values according to the consequent changes in SS. In addition, FIG. 6 is an example depending on the width direction formation position.

According to one example, the width and length of the capping layer may be equal to or smaller than the width and length of the semiconductor layer, respectively. At this time, the width direction of the capping layer refers to the direction of connecting between the source electrode and drain electrode, and the length direction of the capping layer refers to the vertical direction of the width direction.

The width of the capping layer may be within a range of 1% to 50% of the width of the semiconductor layer. In case of the width of the capping layer of 50% or less, when it is partially deposited on the semiconductor layer regardless of the position of the capping layer, the carrier concentration increases on the bottom of the region in which the capping layer is deposited. Then, according to the adjustment of the width of the capping layer, a parasitic channel with low on current and threshold voltage is formed, and therefore, as disclosed in FIG. 5 and FIG. 6, the SS of the transfer curve of the thin film transistor may increase.

The width direction formation position of the capping layer satisfies the value of [Equation 1] below in relation to the semiconductor layer.

$$X = k ( {W}_{CH} - {W}_{CAP} ) , ( 0 \leq k \leq 1 ) \qquad [ Equation 1 ]$$

Herein, X is the width direction distance from one end of the channel to the position where the capping layer starts, and W_{CH} is the width of the channel, and W_{CAP} is the width of the capping layer. SS control depends on the range of the width of the capping layer covering the semiconductor layer. Accordingly, deposition on a portion of the semiconductor layer is a characteristic of SS control, and as FIG. 6, the same effect can be achieved regardless of the position of the capping layer.

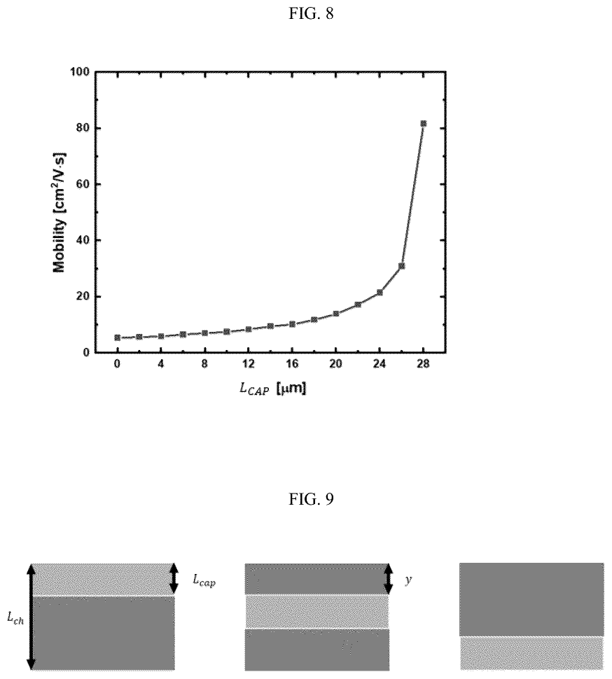

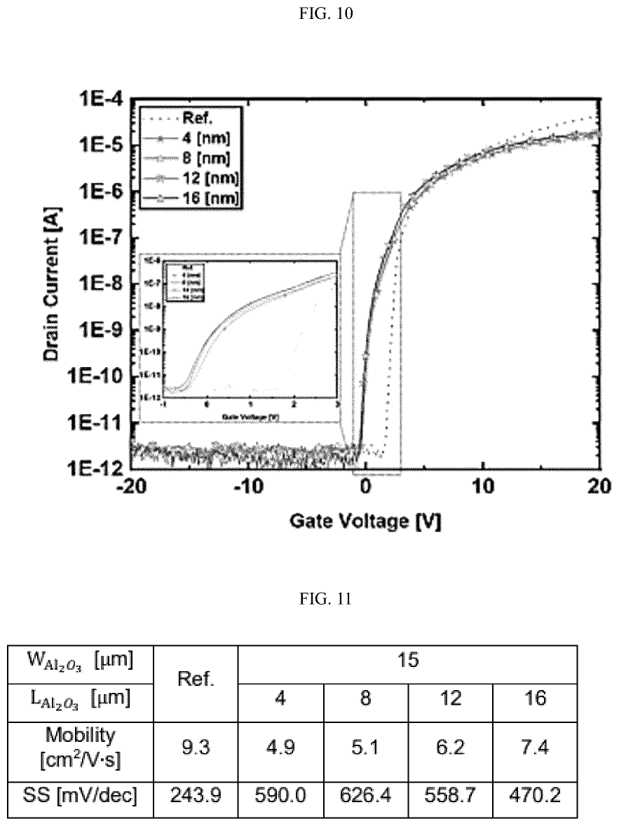

Herein, with FIG. 7, FIG. 8 and FIG. 9, the transfer curve and changes in mobility and SS when the capping layer is formed in the length direction will be described.

FIG. 7 shows the transfer curve when the capping layer is laminated on a portion of the semiconductor layer in the length direction, in case of conducting the experiment with the length of the semiconductor layer of the thin film transistor of 30 μm. FIG. 8 shows the calculated mobility of each thin film transistor as a graph based on the left graph. FIG. 9 is an example according to the length direction formation position.

The length of the capping layer may be 1% to 95% of the length of the semiconductor layer. In case of the length of the capping layer of 95% or less, when it is partially deposited on the semiconductor layer regardless of the position of the capping layer, the mobility of the thin film transistor increases.

As disclosed in FIG. 7 and FIG. 8, it can be confirmed that when the length of the capping layer is 90% or more of the length of the semiconductor length, the mobility reaches 80 cm²/V·s. Considering that a general a-IGZO thin film transistor has mobility of around 10 cm²/V·s and it is called a high-mobility thin film transistor when it has mobility of 50 cm²/V·s or more, it can be confirmed that the thin film transistor of the present invention has a high level of mobility.

The length direction formation position of the capping layer satisfies the value of [Equation 2] below in relation to the semiconductor layer.

$$Y = k ( {L}_{CH} - {L}_{CAP} ) , ( 0 \leq k \leq 1 ) \qquad [ Equation 2 ]$$

Herein, Y is the vertical direction distance in the length direction, and LCH is the length of the semiconductor layer, and LCAP is the length of the capping layer. Mobility control depends on the range of the length of the capping layer covering the semiconductor layer. Accordingly, deposition on a portion of the semiconductor layer is a characteristic of mobility control, and as FIG. 9, the same effect can be achieved regardless of the position of the capping layer.

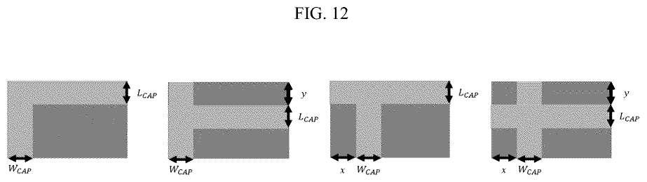

Hereinafter, with FIG. 10, FIG. 11 and FIG. 12, the transfer curve and changes in mobility and SS when the capping layer is formed simultaneously in the length and width direction will be described.

FIG. 10 is a graph of the transfer curve when the capping layer is formed simultaneously in the length and width direction, and FIG. 11 is a table showing the value depending on the subsequent changes in SS. FIG. 12 is an example depending on the position when the length and width direction is simultaneously formed.

According to the above description, it was described that the thin film transistor according to the present invention forms a capping layer in the width direction to control SS and forms a capping layer in the length direction to control mobility. The thin film transistor according to the present invention can not only control SS and mobility, respectively, but also control them simultaneously by overlapping two technologies.

Referring to FIG. 2, FIG. 10 and FIG. 11, which are experiments performed as one example, it could be confirmed that effects which the SS increases when the width of the capping layer is 15 μm, and the mobility increases as the value of the length of the capping layer become larger, when it is formed in a portion of the area of the semiconductor layer simultaneously in the width direction and length direction of the capping layer.

FIG. 12 is an example for the thin film transistor according to the present invention to simultaneously control SS and mobility. Regardless of the position and shape of the width and length of the capping layer, both SS and mobility can be controlled as long as it is formed in a part of the semiconductor layer.

In the above, as one example, the present invention was described as a bottom gate type of oxide semiconductor-based thin film transistor. However, the present invention is not limited to the gate voltage application method of the thin film transistor, and it can be applied for all structures in which capping layers having a function of controlling the concentration of the oxide-based semiconductor layer and carrier are in contact.

Next, the manufacturing method of the thin film transistor according to another example of the present invention will be described.

The manufacturing method of the thin film transistor according to the present invention may comprise preparing a substrate; forming a gate electrode on the substrate; forming an insulating layer on the substrate to cover the gate electrode; forming a semiconductor layer on the insulating layer; forming a source electrode and a drain electrode spaced apart on the semiconductor layer; and forming a capping layer in at least a part of a region between the source electrode and drain electrode on the semiconductor layer.

In the preparing a substrate, it may comprise high concentration of P type doping of a silicon substrate. Before forming an insulating layer, it may further comprise forming (metal film formation and patterning) a gate electrode. The forming an insulating layer may comprise forming an insulating layer comprising SiO₂ on the substrate through an insulating material layer formation process. In the forming an insulating layer, depositing an insulating layer and a gate electrode with a thickness of 100 nm to 200 nm may be comprised.

After depositing the SiO₂, a semiconductor layer may be formed by depositing to amorphous oxide such as a-IGZO, a-ZnO, a-InO, a-ITZO and the like of 10 nm to 40 nm through RF (Radio Frequency) sputtering at a room temperature. Etching it with an acidic solution may be comprised after a process of patterning the semiconductor layer by photolithography.

After forming the semiconductor layer, a source electrode and a drain electrode may be formed on the semiconductor layer spaced apart.

Before forming the capping layer, considering the SS, threshold voltage and mobility values of the thin film transistor, determining a region in which the capping layer is positioned may be comprised. The determining a region in which the capping layer is positioned, may determine at least one of the position, width and length of the capping layer.

After that, the forming a capping layer may use a deposition process. Then, the capping layer may be performed under the same sputtering condition as forming the semiconductor layer. The capping layer may be deposited to 2 nm to 10 nm. The forming a capping layer may comprise patterning through a lift-off process.

The forming a capping layer, may design a capping layer only by introducing an additional process of a simple step to the conventional process of forming a semiconductor layer in the present invention.

The above description of the present invention is merely intended to illustratively describe the technical spirit of the present invention, and various changes and modifications can be made by those skilled in the art without departing from the essential features of the present invention. Therefore, the examples disclosed herein are not intended to limit the technical spirit of the present invention, but are intended to describe the present invention, and the scope of the technical spirit of the present invention is not limited by these examples. The protection scope of the present invention should be construed by the following claims, and all technical spirits within the equivalent scope thereto should be interpreted as being included in the scope of the present invention.

1. A thin film transistor, comprising;
a substrate;
a gate electrode formed on the substrate;
an insulating layer formed on the substrate to cover the gate electrode;
a semiconductor formed on the insulating layer to form a channel;
a source electrode and a drain electrode formed spaced apart from each other on the semiconductor layer; and
a capping layer formed in at least one region between the source electrode and the drain electrode on the semiconductor layer to control the carrier concentration of the channel.

2. The thin film transistor according to claim 1,
wherein the capping layer comprises at least one selected from the group consisting of aluminum oxide (Al₂O₃), silicon oxide (SiO₂), silicon nitride (SiN_{X}) and inorganic insulating materials, and
the carrier concentration of the region in which the capping layer is formed is higher than the carrier concentration of a region in which the capping layer is not formed.

3. The thin film transistor according to claim 1,
wherein the thickness of the capping layer is 2 nm to 10 nm.

4. The thin film transistor according to claim 1,
wherein the width and length of the capping layer are equal to or smaller than the width and length of the channel, respectively.

5. The thin film transistor according to claim 4,
wherein the width of the capping layer is 50% or less of the width of the channel.

6. The thin film transistor according to claim 4,
wherein the width direction formation position of the capping layer satisfies the value of [Equation 1] below in relation to the channel.
$$X = k ( {W}_{CH} - {W}_{CAP} ) , ( 0 \leq k \leq 1 ) \qquad [ Equation 1 ]$$
(Herein, X is the width direction distance from one end of the semiconductor layer to the location where the capping layer starts, and W_{CH} is the width of the channel, and W_{CAP} is the width of the channel)

7. The thin film transistor according to claim 1,
wherein the length of the capping layer is 95% or less of the length of the channel.

8. The thin film transistor according to claim 1,
wherein the length direction formation position of the capping layer satisfies the value of [Equation 2] below in relation to the channel.
$$Y = k ( {L}_{CH} - {L}_{CAP} ) , ( 0 \leq k \leq 1 ) \qquad [ Equation 2 ]$$
(Herein, Y is the length direction distance from one end of the semiconductor layer to the location where the capping layer starts, and Lch is the length of the channel, and Lcap is the length of the capping layer)

9. The thin film transistor according to claim 1,
wherein the semiconductor layer positioned on the bottom of the region in which the capping layer is formed performs the role of an N-type doping region.

10. The thin film transistor according to claim 1,
wherein at least a part of the capping layer is in contact with the source electrode and the drain electrode.

11. A manufacturing method of a thin film transistor, comprising;
preparing a substrate;
forming a gate electrode on the substrate;
forming an insulating layer on the substrate to cover the gate electrode;
forming a semiconductor layer on the insulating layer;
forming a source electrode and a drain electrode spaced apart on the semiconductor layer; and
forming a capping layer in at least a part of a region between the source electrode and drain electrode on the semiconductor layer.

12. The manufacturing method of a thin film transistor according to claim 11,
wherein the forming an insulating layer,
comprises depositing an insulating material with a thickness of 100 nm to 200 nm on the substrate.

13. The manufacturing method of a thin film transistor according to claim 11,
wherein the forming a capping layer comprises forming the capping layer through a sputtering method at a room temperature.

14. The manufacturing method of a thin film transistor according to claim 11,
comprising determining a region in which the capping layer is to be positioned in consideration of the SS, threshold voltage and mobility values of the thin film transistor,
before the forming the capping layer.

15. The manufacturing method of a thin film transistor according to claim 14,
wherein the determining a region in which the capping layer is to be positioned determines at least one of the location, width and length of the capping layer.

16. The manufacturing method of a thin film transistor according to claim 11,
wherein the driving device of the thin film transistor is the thin film transistor of claim 1.

17. A circuit for displays comprising a thin film transistor, which is a circuit for displays comprising at least one thin film transistor for a switching or driving purpose,
wherein the thin film transistor is the thin film transistor of claim 1.
